(19) United States
(12) Patent Application Publication
(10) Pub. No.: US 2012/0126275 A1
(43) Pub. Date: May 24, 2012

(54) LIGHT-EMITTING DIODE WITH COMPENSATING CONVERSION ELEMENT AND CORRESPONDING CONVERSION ELEMENT

(75) Inventor: Dominik Eisert, Regensburg (DE)

(73) Assignee: OSRAM OPTO SEMICONDUCTORS GMBH, Regensburg (DE)

(21) Appl. No.: 13/386,063

(22) PCT Filed: Jun. 29, 2010
(86) PCT No.: PCT/EP2010/059180

§ 371 Date: Feb. 8, 2012

(30) Foreign Application Priority Data
Jul. 29, 2009 (DE) 10 2009 035 100.0

(51) Int. Cl. H01L 33/50; C09K 11/08

(52) U.S. Cl. 257/98; 252/301.4 R; 257/E33.061

(57) ABSTRACT

A light-emitting diode includes a light-emitting diode chip which emits primary radiation in a spectral range of blue light during operation; a conversion element including a first phosphor and a second phosphor which absorbs part of the primary radiation and re-emits secondary radiation, wherein the first phosphor has, in an absorption wavelength range (Δλ_{ab}), an absorption that decreases as the wavelength increases, and the second phosphor has, in the same absorption wavelength range (Δλ_{ab}), an absorption that increases as the wavelength increases; the primary radiation includes wavelengths that lie in the absorption wavelength range (Δλ_{ab}); and the light-emitting diode emits white mixed light including primary radiation and secondary radiation and having a color temperature of at least 4000 K.

### RELATED APPLICATIONS

This is a §371 of International Application No. PCT/EP2010/059180, with an international filing date of Jun. 29, 2010 (WO 2011/012388 A1, published Feb. 3, 2011), which is based on German Patent Application No. 10 2009 035 100.00, filed Jul. 29, 2009, the subject matter of which is incorporated by reference.

### TECHNICAL FIELD

This disclosure relates to a light-emitting diode, particularly to a conversion element for a light-emitting diode.

### BACKGROUND

WO 2008/020913 A2 describes a conversion element for generating warm-white mixed light.

However, it could be helpful to provide a light-emitting diode which generates electromagnetic radiation whose color locus is particularly insensitive to fluctuations in operating current and/or operating temperature of the light-emitting diode. In particular, it could be helpful to provide a light-emitting diode suitable for generating cold-white light.

### SUMMARY

I provide a light-emitting diode including a light-emitting diode chip which emits primary radiation in a spectral range of blue light during operation, a conversion element including a first phosphor and a second phosphor which absorbs part of the primary radiation and re-emits secondary radiation, wherein the first phosphor has, in an absorption wavelength range (Δλ_{ab}), an absorption that decreases as the wavelength increases, and the second phosphor has, in the same absorption wavelength range (Δλ_{ab}), an absorption that increases as the wavelength increases, the primary radiation includes wavelengths that lie in the absorption wavelength range (Δλ_{ab}), and the light-emitting diode emits white mixed light including primary radiation and secondary radiation and having a color temperature of at least 4000 K.

I also provide a conversion element for a light-emitting diode, the conversion element provided to absorb a primary radiation and emit a secondary radiation, including a first phosphor and a second phosphor, wherein the first phosphor has, in an absorption wavelength range (Δλ_{ab}), an absorption that decreases as the wavelength increases, and the second phosphor has, in the same absorption wavelength range (Δλ_{ab}), an absorption that increases as the wavelength increases, and wavelengths of the maximum emission intensity of the first and second phosphors differ by at most 20 nm.

I further provide a light-emitting diode including a light-emitting diode chip which emits primary radiation in a spectral range of blue light during operation, a conversion element including a first phosphor and a second phosphor which absorbs part of the primary radiation and re-emits secondary radiation, wherein the first phosphor has, in an absorption wavelength range (Δλ_{ab}), an absorption that decreases as the wavelength increases, and the second phosphor has, in the same absorption wavelength range (Δλ_{ab}), an absorption that increases as the wavelength increases, the primary radiation includes wavelengths that lie in the absorption wavelength range (Δλ_{ab}), the light-emitting diode emits white mixed light including primary radiation and secondary radiation and having a color temperature of at least 4000 K, the first phosphor is based on europium as a luminous center and the second phosphor is based on cerium as a luminous center, and the weight ratio of the first phosphor to the second phosphor is 0.60 to 1.5.

### BRIEF DESCRIPTION OF THE DRAWINGS

FIGS. 1, 2A, 2B, 3A, 3B and 4 to 9 are graphical illustrations of light-emitting diodes and conversion elements.

FIGS. 10A to 10D are schematic sectional illustrations showing different examples of light-emitting diodes and conversion elements.

### DETAILED DESCRIPTION

We provide a light-emitting diode that may comprise a light-emitting diode chip. The light-emitting diode chip has, for example, a semiconductor body composed of an inorganic semiconductor material. The semiconductor body comprises one or a plurality of active zones provided for generating electromagnetic radiation. During operation, the light-emitting diode chip preferably emits primary radiation in the spectral range of ultraviolet radiation and/or blue light. That is to say that, during operation of the light-emitting diode chip, ultraviolet radiation and/or blue light is emitted by the light-emitting diode chip. The electromagnetic radiation emitted by the light-emitting diode chip is in this case the primary radiation of the light-emitting diode.

The light-emitting diode may comprise a conversion element. The conversion element is provided for absorbing at least part of the primary radiation of the light-emitting diode chip. That is to say that, during the operation of the light-emitting diode, the light-emitting diode chip emits the primary radiation and the latter passes at least partly into the conversion element, by which it is in turn partly absorbed. The conversion element is excited by the absorbed primary radiation to re-emit a secondary radiation. That is to say that, during operation of the light-emitting diode, the conversion element re-emits secondary radiation. In this case, the secondary radiation preferably has wavelengths that are greater than wavelengths of the primary radiation.

The conversion element may comprise a first phosphor and a second phosphor. That is to say that the conversion element is not formed with a single phosphor suitable for absorbing and re-emitting electromagnetic radiation, but rather with two different phosphors. In this case, the conversion element can also be formed with more than two phosphors. All that is important is that the conversion element is formed at least with a first phosphor and with a second phosphor.

The conversion element may have an absorption wavelength range. Electromagnetic radiation lying in the absorption wavelength range is absorbed by the conversion element. The absorbed radiation can excite the conversion element to re-emit secondary radiation. In this case, the absorption wavelength range does not have to be the entire wavelength range in which the phosphor can absorb primary radiation and re-emit secondary radiation, rather a section of this wavelength range can be involved.

The first phosphor of the conversion element may have, in the absorption wavelength range, an absorption that decreases as the wavelength increases. That is to say that, within the absorption wavelength range, the first phosphor has a higher absorption and a lower absorption, wherein the first phosphor has the lower absorption at higher wavelengths than the higher absorption. By way of example, the absorption of the first phosphor in the absorption wavelength range falls continuously as the wavelength increases.

The second phosphor may have, in the same absorption wavelength range, an absorption that increases as the wavelength increases. That is to say that, within the absorption wavelength range, the second phosphor has a higher absorption and a lower absorption, wherein the second phosphor has the lower absorption at lower wavelengths than the higher absorption. By way of example, the absorption of the second phosphor in the absorption wavelength range rises continuously as the wavelength increases.

In other words, the absorption behavior of the two phosphors in the absorption wavelength range is mutually opposite. As the wavelength increases, absorption of the first phosphor decreases, whereas absorption of the second phosphor increases. The absorption wavelength range is then formed at least by a section of that wavelength range in which this statement is applicable.

The primary radiation may comprise wavelengths lying in the absorption wavelength range. That is to say that the primary radiation comprises wavelengths lying in that wavelength range in which the absorption behavior of the first and second phosphors is mutually opposite.

The light-emitting diode may emit white mixed light composed of primary radiation and secondary radiation. In this case, the mixed light has a color temperature of at least 4000 K. By way of example, the color temperature is then at most 7000 K. That is to say that the white mixed light is cold-white light.

The light-emitting diode may comprise a light-emitting diode chip which emits primary radiation in the spectral range of blue light during the operation of the light-emitting diode. Furthermore, the light-emitting diode comprises a conversion element which absorbs part of the primary radiation and re-emits secondary radiation. In this case, the conversion element comprises a first phosphor and a second phosphor. The first phosphor has, in an absorption wavelength range, an absorption that decreases as the wavelength increases, and the second phosphor has, in the same absorption wavelength range, an absorption that increases as the wavelength increases. In this case, the primary radiation comprises wavelengths lying in the absorption wavelength range and the light-emitting diode emits white mixed light composed of primary radiation and secondary radiation and having a color temperature of at least 4000 K.

Furthermore, we provide a conversion element for a light-emitting diode. The conversion element is suitable for use with a light-emitting diode chip. By way of example, the conversion element is suitable for a light-emitting diode. That means that all the features disclosed for the conversion element are also disclosed for the light-emitting diode and vice versa.

The conversion element is provided to absorb primary radiation and emit secondary radiation. Preferably, the secondary radiation comprises higher wavelengths than the primary radiation.

The conversion element may comprise a first phosphor and a second phosphor, wherein the first phosphor has, in an absorption wavelength range, an absorption that decreases as the wavelength increases, and the second phosphor has, in the same absorption wavelength range, an absorption that increases as the wavelength increases.

The wavelengths of the maximum emission intensity of the first and second phosphors may differ by at most 20 nm. In other words, the first phosphor and the second phosphor have a different wavelength of the maximum emission intensity. In this case, the difference in the wavelength of the maximum emission intensity is, however, at most 20 nm. The difference is preferably at most 10 nm, particularly preferably at most 7 nm.

In other words, the two phosphors emit light of the same color, wherein the maximum in the emission of the two phosphors can be slightly shifted relative to one another.

The following examples relate both to the light-emitting diode and to the conversion element.

The secondary radiation emitted by the conversion element may lie in the spectral range of yellow light. That is to say, in particular, that both phosphors of the conversion element emitting electromagnetic radiation in the spectral range of yellow light, wherein the wavelengths of the maximum emission intensity can be shifted relative to one another, as described above.

The wavelength of the maximum emission intensity of the second phosphor may be greater than that of the first phosphor. That is to say that the second phosphor has its maximum emission at a wavelength that is greater than the wavelength at which the second phosphor has its maximum emission.

The first phosphor may be based on europium (Eu) as a luminous center and the second phosphor is based on cerium (Ce) as a luminous center. Preferably, the second phosphor based on cerium as a luminous center has a wavelength of the maximum emission intensity that is somewhat greater than the wavelength of the maximum emission intensity of the first phosphor based on Eu as a luminous center.

The maximum of the emission intensity of the primary radiation, that is to say of the electromagnetic radiation emitted by the light-emitting diode chip, may lie between at least 440 nm and at most 470 nm, preferably between 445 nm and 460 nm. In this case, the wavelength range of the primary radiation preferably forms the absorption wavelength range in which the first phosphor has an absorption that decreases as the wavelength increases, and the second phosphor has an absorption that increases as the wavelength increases.

The absorption of the conversion element may fall by at most 35% in the absorption wavelength range, that is to say in particular in the wavelength range of at least 440 nm to at most 470 nm. In this case, the absorption of the conversion element is the summed absorption of the phosphors of the conversion element.

The first phosphor and the second phosphor may be based on cerium as a luminous center, wherein the absorption wavelength range of one of the phosphors is shifted relative to the other phosphor by changing the composition of the host lattice of the phosphor. This results in total in a wider absorption band than for the individual phosphors. The gallium-containing system YAG:Ce and Y(Ga,Al)G:Ce is appropriate as an example.

The weight ratio of the first phosphor in the conversion element to the second phosphor in the conversion element may be between at least 0.6 and at most 1.5. By way of example, the following weight ratios of the first phosphor to the second phosphor are particularly preferred: 2:3, 7:8, 1:1, 8:7, 3:2.

Such weight ratios of the first phosphor to the second phosphor make it possible to provide a conversion element in which the absorption in the absorption wavelength range of the conversion element is virtually constant, that is to say hardly falls, for example. A light-emitting diode comprising such a conversion element is therefore particularly insensitive to changes in the wavelength of the primary radiation.

The light-emitting diode may comprise at least two light-emitting diode chips, wherein the maximum of the emission intensity of two of the light-emitting diode chips of the light-emitting diode differs from one another by at least 5 nm. That is to say that the two light-emitting diode chips are not presorted particularly precisely, but rather have a relatively large difference in the dominant wavelength of their primary radiation. A conversion element described here is disposed downstream of the light-emitting diode chips of the light-emitting diode. On account of the wide, virtually uniform absorption of the conversion element, despite the use of light-emitting diode chips having a dominant wavelength greatly different from one another, a light-emitting diode is provided which can emit white mixed light in a predeterminable, well-defined color locus range. The color locus of the white light generated has hardly any spatial fluctuations despite the use of different light-emitting diode chips.

The light-emitting diode described here and also the conversion element described here are explained in greater detail below on the basis of examples and associated figures.

Elements that are identical, of identical type or act identically are provided with the same reference symbols in the figures. The figures and the size relationships of the elements illustrated in the figures among one another should not be regarded as to scale. Rather, individual elements may be illustrated with an exaggerated size to enable better illustration and/or to afford a better understanding.

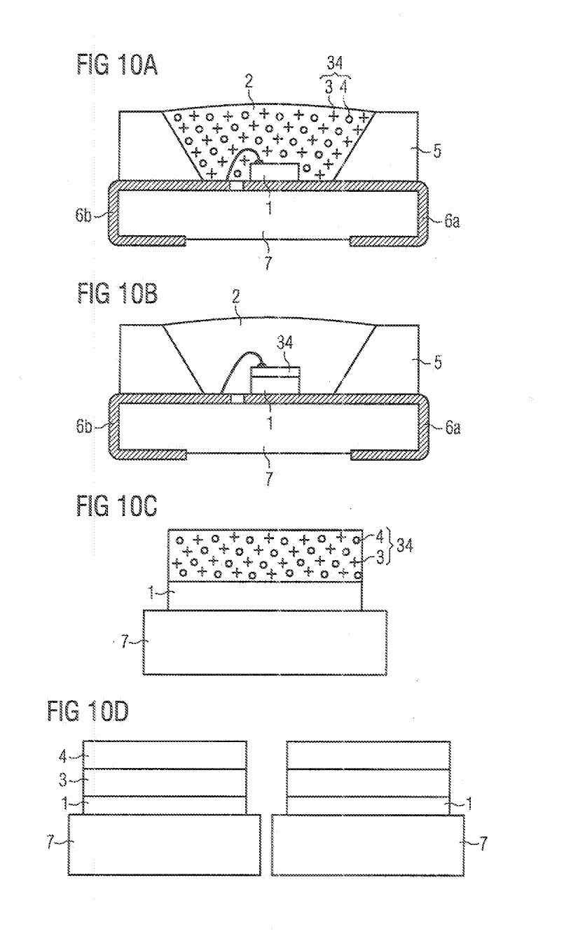

Light-emitting diodes that emit white light can be produced from a blue-emitting light-emitting diode chip 1 and a yellow-emitting conversion element 34 as seen in FIGS. 10A to 10D. That is to say that the light-emitting diode chip 1 emits blue primary radiation, while the conversion element 34 emits yellow secondary radiation.

In this case, the conversion element 34 absorbs part of the blue light, this part then being re-emitted in the yellow spectral range. The transmitted part of the blue light with the converted yellow light together produce the white color impression. The construction of the light-emitting diode can be kept very compact if the blue light-emitting diode chip 1 is enveloped with the conversion element 34 as shown in FIGS. 10B to 10D.

Blue light-emitting diode chips 1 are based, for example, on the material system GaInN. The emission wavelength can be set by the indium (In) content in a wide range of the visible spectrum, for example, from approximately 360 nm to approximately 600 nm. In this case, the spectral range of 440 nm to 470 nm is preferably used for white light-emitting diodes.

In the case of the LED phosphors, one material that is particularly well suited is cerium-doped YAG (Y₃Al₅O₁₂), or certain modifications with Gd, Tb or Ga. The cerium-doped phosphors have a strong absorption band in the blue spectral range and emit in the yellow region, that is to say are outstandingly suitable for white light-emitting diodes. However, other yellow-emitting phosphors based on europium as a luminous center also prove to be advantageous. These include, for example, the orthosilicates (Ca, Sr, Ba)SiO₄:Eu or the oxynitrides (Ca, Sr, Ba)Si₂O₂N₂:Eu.

The human eye reacts very sensitively to small color differences. Therefore, during production of white luminous means, attempts are made to keep the color locus variation within a small bandwidth. In the case of white light-emitting diodes, one important contribution to the color locus variation is the spectral variation of the light emitted by the light-emitting diode chip 1. The variation of the emission wavelength in the production process has a certain range. It may likewise be logistically advantageous to be able to mix light-emitting diodes having different emission wavelengths in the products.

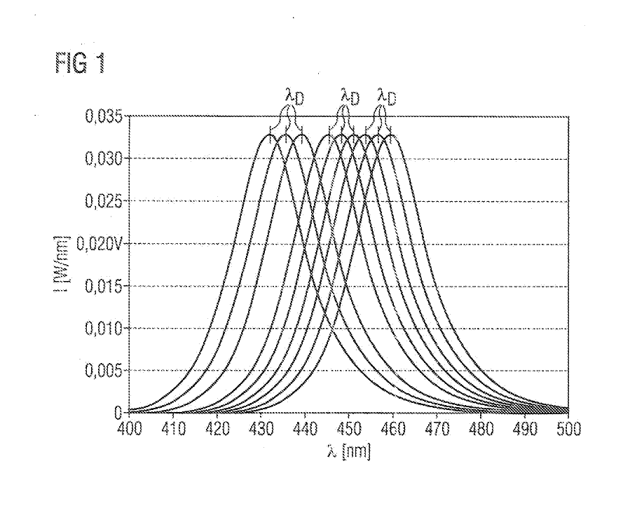

FIG. 1 shows a series of spectra of blue light-emitting diode chips 1 from the relevant spectral range. In this case, the emission spectra of the blue light-emitting diode chips extend over wavelengths of the maximum emission intensity, that is to say the dominant wavelengths λ_{D} of at least 440 nm to at most 470 nm. In FIG. 1, the intensity I is plotted against the wavelength λ.

The second spectral variation occurs in the application of the light-emitting diode itself. Thus, the emission wavelength of a light-emitting diode chip shifts both with the operating current I and with the operating temperature T.

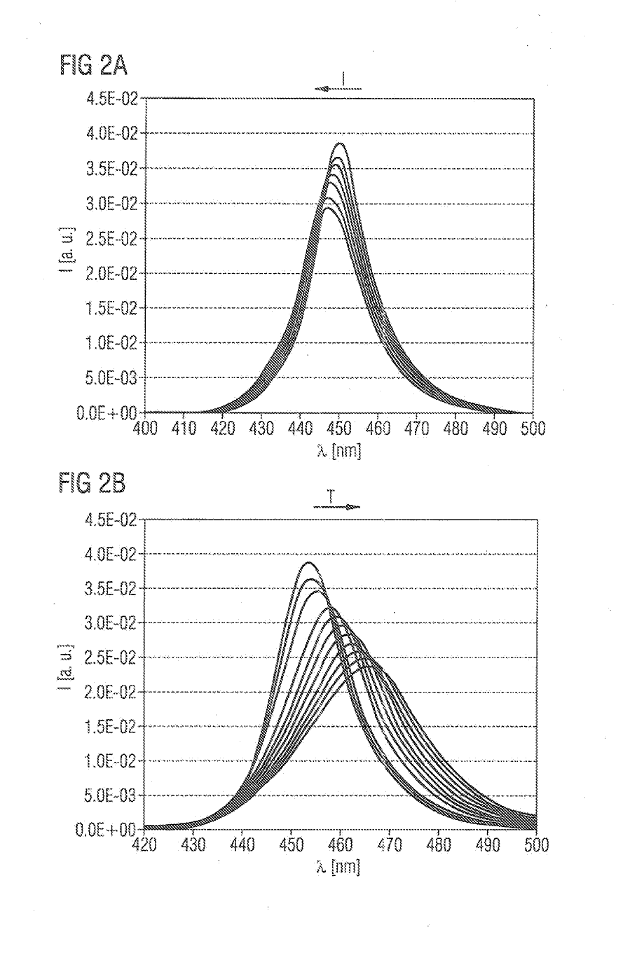

In this respect, FIG. 2A shows the spectral variation during the operation of a blue light-emitting diode chip 1 with the operating current I. The wavelengths of the maximum emission intensity shift toward smaller wavelengths as the current I increases.

FIG. 2B shows the spectral variation during operation of a blue light-emitting diode chip 1 with operating temperature T. The wavelengths of the maximum emission intensity shift toward greater wavelengths as the temperature T increases. Hence, the spectra become wider.

The change in the spectrum of the blue light-emitting diode chip 1 also has effects on the color locus of the white light-emitting diode. The absorption behavior of the phosphors used is itself also spectrally dependent. As a result, the quantity of the absorbed blue and/or re-emitted yellow light changes, which leads to a blue and/or yellow shift in the white mixed light of the white LED.

In production, attempts are made to avoid the problem by carrying out a presorting of the semiconductors according to emission wavelength (so-called “binning”). However, such sorting is time- and cost-intensive, and it additionally leads to losses in yield as a result of light-emitting diode chips that cannot be utilized. The requirement for closely sorted groups is increasing. Hence, a supply bottleneck may arise in the future.

Furthermore, in the field of light-emitting diode technology, wafer level processes are also conceivable wherein wavelength sorting is not possible, since, for example, a wafer comprising a multiplicity of light-emitting diode chips is intended to be coated with a common conversion element. In this case, therefore, tolerant processes must provide for the necessary accuracy.

In the field of light-emitting diode applications, too, color locus variation poses problems. Thus, by way of example, a pulse width modulation is used for brightness dimming to avoid a color locus drift as a result of current density effects. Devices that are stable with respect to color locus would make it possible to revert to simpler current-driven driving systems. The air conditioning of the devices could also be dimensioned in a simpler manner.

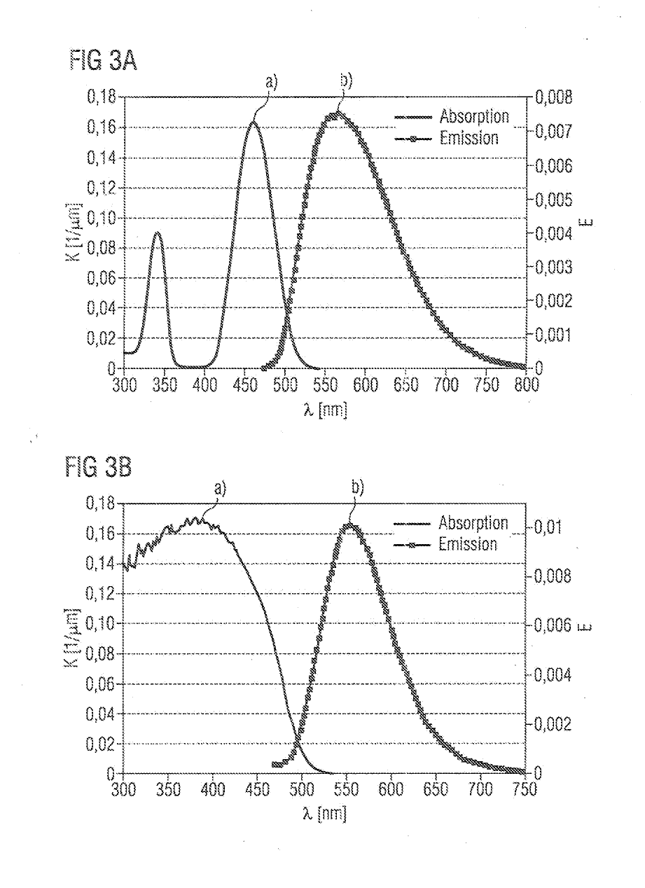

The absorption and emission behavior of a second, cerium-doped phosphor 4 is illustrated in greater detail in FIG. 3A. In curve a), the absorption K is plotted against the wavelength λ. In curve b), the emission intensity E is plotted against the wavelength λ.

The absorption and emission behavior of a first, Eu-doped oxynitride phosphor 3 is illustrated in greater detail in FIG. 3B. In curve a), the absorption K is plotted against the wavelength λ. In curve b), the emission intensity E is plotted against the wavelength λ.

To determine the spectra, the following should be noted:
The spectra of the blue light-emitting diode chips were measured on (Ga, In)N-based light-emitting diodes. The emission spectra of the phosphors were measured on powder samples. The absorptance was able to be determined from reflection measurements. The Kubelka-Munk method was used for evaluating the data. The absorptance relates to the Kubelka-Munk parameter K, which represents the attenuation in the propagation direction.

A certain part of the change in the white color locus in the event of a change in the emission of the light-emitting diode chip 1 is based on the color shift of the blue light per se. However, the greater part of the color locus shift is caused by the spectral dependence of the absorption by the phosphor. As can be seen in FIGS. 3A and 3B, the phosphors have absorption edges that rise steeply precisely in the blue spectral range of relevance. Small spectral changes in the excitation therefore have a great effect on the later color locus. The dependencies are governed by the atomic structure of the phosphors and, unlike the emission wavelength, can scarcely be influenced. A small shift in the absorption band is possible in the case of YAG-based phosphors, for example, by adding gallium, but does not change anything about the basic form of the absorption curve.

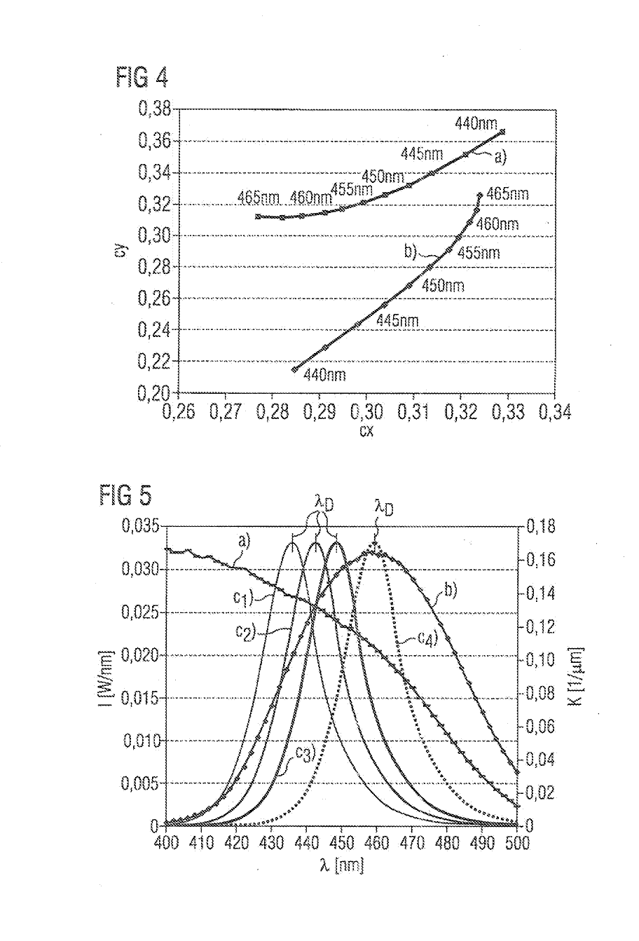

FIG. 4 shows the color shift when using different emission wavelengths for the same conversion layer. In this case, FIG. 4 shows the calculated color locus for light-emitting diode chips 1 having a different blue emission wavelength given the same configuration of the conversion element. Curve a) was calculated for the first phosphor 3, and curve b) was calculated for the second phosphor 4.

The color space spanned is unacceptably large. Therefore, sorting and control of the conversion element is necessary. However, even that enables the required accuracies to be achieved only with difficulty.

For the cerium-doped garnet phosphor 4, the yellow component increases as the emission wavelength increases, while for the Eu-doped oxynitride, the first phosphor 3, the yellow component decreases. This can also be discerned from the compilation of the absorption bands for the first phosphor 3, curve a), and the second phosphor 4, curve b), with the emission spectra for different blue light-emitting diode chips 1 (see FIG. 5).

One concept of the conversion element and of a light-emitting diode is, then, that of using a phosphor mixture wherein the components have, in the range of the blue light-emitting diode chip wavelength used, a mutually opposite absorption behavior. Through a suitable choice of the concentration ratios, it is thus possible to establish a wide constant absorption band. Since the emission colors of the two phosphors are close together, it is possible to use almost any desired concentrations without influencing the white point.

There is a differentiation with respect to warm-white light-emitting diodes having color temperatures around 3000 K. In the case of the latter, a phosphor mixture composed of a yellow and a red phosphor could be used. However, the concentration would not be freely selectable since the color locus would simultaneously have to be set by the ratio. In this case, by way of example, the proportion of the Eu-doped red phosphor would have to be chosen to be significantly smaller such that the variation in the absorption behavior cannot be obtained.

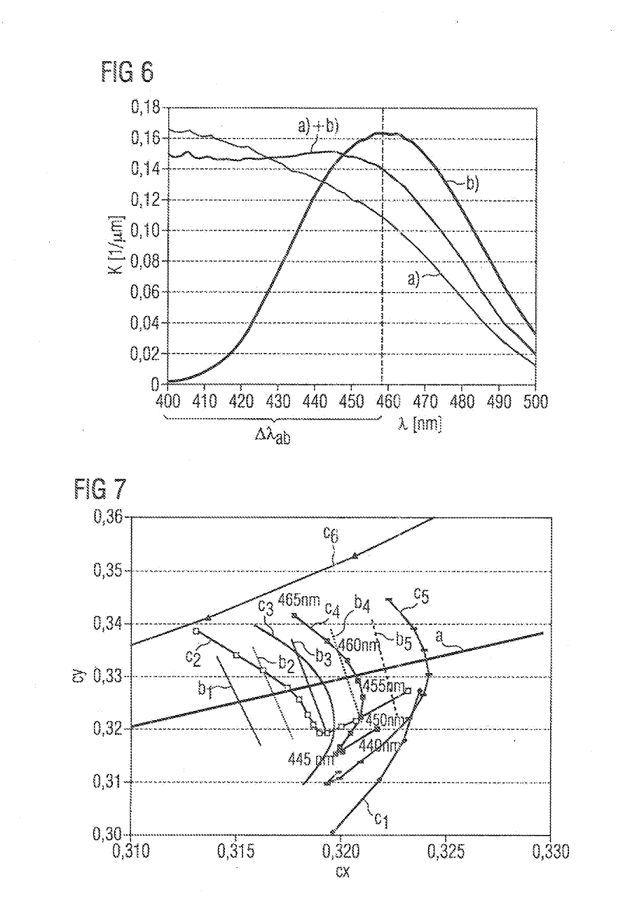

FIG. 6 shows the combination of cerium-doped second phosphor, curve b), and Eu-doped first phosphor, curve a). In the mixture, curve a+b), it is possible to establish an almost constant absorption K for wavelengths of <460 nm. In the absorption wavelength range Δλ_{ab}, in particular in the wavelength range of at least 440 nm and at most 470 nm, that is to say the absorption wavelength range Δλ_{ab}, the absorption K of the conversion element 34 comprising first phosphor 3 and second phosphor 4 falls by at most 35%.

The positive effect on the color locus variation can be seen in FIG. 7. Curves c1, c6 relate to the pure phosphors. In this case, only a small portion of the possible excitation wavelengths is situated in the color field shown. That is different in the case of the phosphor mixtures used. Here the color loci for all emission wavelengths used are situated within the diagram. It is even possible to maintain the color temperature within a range of approximately 100 K (the depicted Judd straight lines of the same color temperature have a distance of 100 K). The color loci lie within a window of Δcx=0.005, which represents a very narrow distribution. Curves c2, c3, c4 and c5 show weight mixing ratios of the second phosphor to the first phosphor of 7:8, 1:1, 8:7, and 3:2. Curve a) is the Planck curve. The wavelength separation between two markings is in each case 2.5 nm in FIG. 7.

The color locus shift with the operating current can also be significantly reduced by using the phosphor mixture. In the case of a Δcx=0.001, the shift is virtually unmeasurable, and dimming of the light-emitting diode is therefore possible without additional measures, without the color locus of the white mixed light being appreciably shifted.

The concentrations to obtain a narrow distribution, in the case of the phosphors used, range around the ratio of 1:1 of the volume of the first phosphor 3 to the volume of the second phosphor 4. A slight excess of second phosphor 4, for example, YAG:Ce, obtains the least variation over the entire range. If the blue wavelength range is restricted, that is to say without the use of extremely long- and short-wave diodes, then a slight excess of first phosphor 3, for example, SiON:Eu, can also obtain narrow distributions.

The indication of a concentration depends, of course, on the absorptivity manifested by the phosphor. In the example shown, both phosphors have the same maximum absorptivity, relative to the phosphor volume, in the relevant wavelength range. Therefore, identical concentrations achieve the best result. However, it may also be expedient to vary the doping concentration of one phosphor. Lower cerium dopings result in an improved high-temperature behavior in YAG:Ce, for example. The phosphor color is likewise set by the doping concentration. The concentration indications given here therefore relate to a lesser extent to the total mass of the phosphor, but rather to the content of luminous centers.

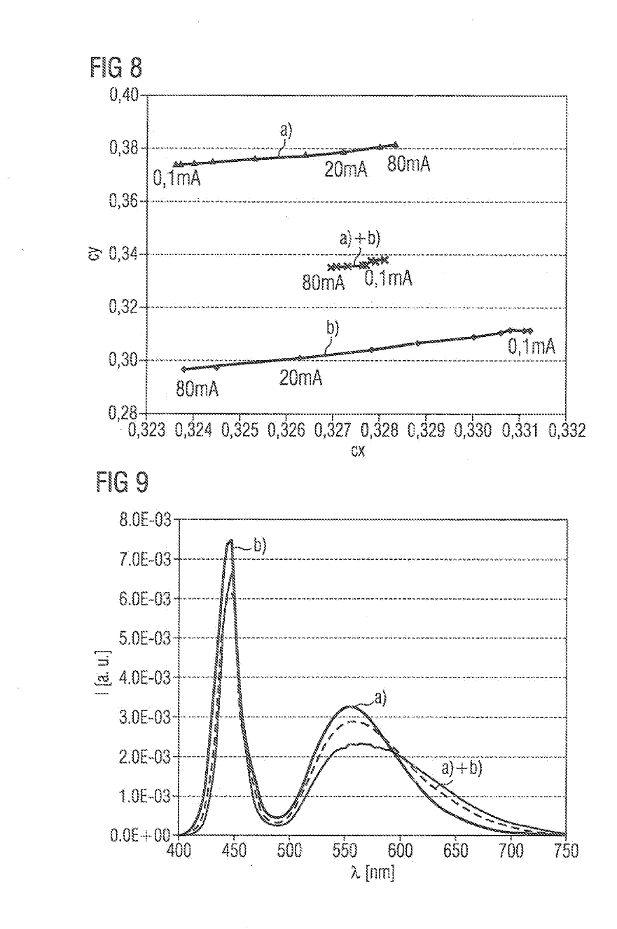

FIG. 8 shows the color locus shift upon a change in the operating current I for conversion elements concerning the first phosphor 3 (curve a)), the second phosphor 4 (curve b)) and the first and second phosphors (curve a+b)).

The explanations considered here preferably relate to the color region designated as “cold-white,” having color temperatures of between 4000 K and 7000 K in the region of the Planckian color progression. In this case, the adherent color of the conversion element 34 is in the region around 570 nm, with a variation range of approximately +/−5 nm. Low color temperatures require a longer emission wavelength, and colder white requires a lower wavelength. The emission color of the light-emitting diode chips is intended to vary in the range of 440 nm to 470 nm. A restricted range of approximately 445 nm to 460 nm is preferred. Here, too, the light-emitting diodes will be chosen in the longer-wave range for lower color temperatures.

For the selection of the phosphors, the cerium-doped garnet phosphors are appropriate as second phosphors 4. A typical representative is YAG:Ce having an emission wavelength of 572 nm, for example. The color is concomitantly determined by the cerium content; lightly doped phosphors exhibit a short-wave shift. Other representatives are (Lu, Y)(Ga, Al)G:Ce having short-wave shifted emission and absorption, and also (Gd, Y)AlG:Ce having long-wave shifted emission. It is possible to substitute yttrium with terbium or praesodymium instead of cerium. Combinations of the compositions are possible.

Various classes of the Eu²⁺-doped phosphors are appropriate as the first phosphor 3 having a wavelength of the maximum emission intensity which is lower than that of the second phosphor 4. Possible materials are the thiogallates (Mg, Ba, Sr)Ga₂S₄, although with preferably a greenish emission color. The orthosilicates (Ca, Mg, Ba, Sr)SiO₄ have representatives having yellow emission. The class of oxynitrides (Ba, Sr, Ca)Si₂O₂N₂:Eu²⁺ is preferred. These phosphors emit in the yellow spectral range. One important selection criterion for this purpose is the conversion efficiency at elevated temperature (temperature quenching). At 150° C., a YAG:Ce_{0.02} still has 90% of its conversion efficiency at room temperature. The thiogallates and orthosilicates are at approximately 80%, and significantly lower at even higher temperatures. By contrast, at 150° C., the oxynitrides are still at 95% of their room temperature performance, and a system that can be used even at high temperatures can thus be assembled by combining garnet and oxynitride.

As an alternative to the traditional phosphors, it is also possible to use semiconductors or semiconductor nanoparticles since they exhibit an absorption that increases toward shorter wavelengths. By way of example, the class of II/VI compound semiconductors (Zn, Mg, Cd)(S, Se), or (Ga, In)N, exhibits emission in the yellow region.

The emission color of the two different phosphors can lie in the yellow spectral range in one example. In a first example it would be attempted to coordinate the emission wavelength of both phosphors with one another as well as possible. It is then unimportant which phosphor contributes to the emission to an increased extent. What is disadvantageous about this method is that, as a result of the color locus shift of the blue light-emitting diode chip, a certain color locus spreading in the red-green direction cannot be avoided. This method can therefore be advantageously used at low color temperatures with a higher degree of conversion, since the spreading decreases here.

In a second example it is appropriate for the emission wavelengths to be shifted relative to one another by a few nanometers, preferably by less than 7 nm. The second phosphor is preferably subjected to a long-wave shift. As a result, long-wave emitting chips are drawn downward in the color locus such that it is also possible to achieve a delimitation of the color locus in the red-green axis.

For more exact color locus control, it is also possible to use a mixture of three or more phosphors, wherein the additional phosphors can again belong to the class of cerium-doped or Eu-doped phosphors.

FIG. 9 shows the spectral profile of the white light-emitting diode for the individual phosphors and the mixture (curve a+b)). The spectrum of the second phosphor (curve b)) has a full width at half maximum of approximately 100 nm. The spectrum of the first phosphor (curve a)) exhibits a somewhat narrower band (approximately 70-80 nm). That has a positive effect on the visual efficiency since the maximum of the eye sensitivity is at 555 nm.

The color locus calculation for the light-emitting diode was also again effected by the Kubelka-Munk method taking account of scattering, absorption and emission with full spectral dependence.

FIGS. 10A to 10D show examples of light-emitting diodes and conversion elements 34 in schematic sectional illustrations.

In a first example, FIG. 10A, the phosphor pairs are used in a mixture. For this purpose, the phosphor powders for forming the conversion element 43 are weighed together in the correct ratio and subsequently mixed into a matrix material 2, for example, a silicone or epoxy resin or a glass. This conversion element 43 is filled into the cavity of an LED, wherein the total concentration of the phosphor mixture is coordinated with the height of the cavity, which is defined by the housing basic body 5.

In a further form of application, FIG. 10B, the conversion element 34 is arranged around the light-emitting diode chip 1. For this purpose, by way of example, highly concentrated thin layers of the conversion element 34 are produced. The phosphor can be injection-molded, printed, laminated or sedimented around the light-emitting diode chip 1. It is also possible to produce the layer separately with subsequent adhesive bonding. The layer can be applied as a mixture, as illustrated in FIG. 10C.

Besides the use of a mixture, it is also possible to use layer stacks as shown in FIG. 10D. In this case, by way of example, two films comprising the phosphors 3, 4 are combined. It is likewise possible to use combinations of coating and volume potting. The order of the phosphors is not of major importance since the phosphors do not mutually absorb one another.

It is furthermore also possible to use for the conversion element 34 a carrier composed of one of the phosphors, on which the other phosphor is arranged. By way of example, the carrier can consist of a cerium-doped YAG ceramic, on which the second phosphor is deposited or introduced in a matrix material.

Our LEDs and conversion elements are not restricted to the examples by the description. Rather, this disclosure encompasses any novel feature and also any combination of features, which in particular includes any combination of features in the appended claims, even if the feature or combination itself is not explicitly specified in the claims or examples.

1. A light-emitting diode comprising:
a light-emitting diode chip, which emits primary radiation in a spectral range of blue light during operation;
a conversion element, comprising a first phosphor and a second phosphor which absorbs part of the primary radiation and re-emits secondary radiation, wherein
the first phosphor has, in an absorption wavelength range(Δλ_{ab}), an absorption that decreases as the wavelength increases, and the second phosphor has, in the same absorption wavelength range (Δλ_{ab}), an absorption that increases as the wavelength increases;
the primary radiation comprises wavelengths that lie in said absorption wavelength range (Δλ_{ab}), and
the light-emitting diode emits white mixed light comprising primary radiation and secondary radiation and having a color temperature of at least 4000 K.

2. The light-emitting diode according to claim 1, wherein the first phosphor and the second phosphor emit light of the same color, and the wavelengths of maximum emission intensity of the first and second phosphors are slightly shifted relative to one another.

3. The light-emitting diode according to claim 1, wherein wavelengths of the maximum emission intensity of the first and second phosphors differ by at most 20 nm.

4. The light-emitting diode according to claim 1, wherein the secondary radiation lies in the spectral range of yellow light.

5. The light-emitting diode according to claim 1, wherein the wavelength of the maximum emission intensity of the second phosphor is greater than that of the first phosphor.

6. The light-emitting diode according to claim 1, wherein the first phosphor is based on europium as a luminous center and the second phosphor is based on cerium as a luminous center.

7. The light-emitting diode according to claim 1, wherein the second phosphor comprises (Gd,Lu,Y)(Al,Ga)G:Cer³⁺.

8. The light-emitting diode according to claim 1, wherein the first phosphor comprises (Ca,Sr,Ba):SiO₄:Eu²⁺ and/or (Ca,Sr,Ba):Si₂O₂N₂:Eu²⁺.

9. The light-emitting diode according to claim 1, wherein a maximum of the emission intensity of the primary radiation (λ_{D}) lies between at least 440 nm and at most 470 nm.

10. The light-emitting diode according to claim 1, wherein the first phosphor and the second phosphor are based on cerium as a luminous center, and the absorption wavelength range (Δλ_{ab}) of one of the phosphors is shifted relative to the other phosphor by changing the composition of a host lattice of the phosphor.

11. The light-emitting, diode according to claim 10, wherein one of the phosphors is or contains YAG:Ce and the other phosphor is or contains Y(Ga,Al):G:Ce.

12. The light-emitting diode according to any of the preceding claim 1, wherein the absorption of the conversion element falls by at most 35% in the absorption wavelength range (Δλ_{ab}), in particular in the wavelength range of at lest 440 nm and to 470 nm.

13. The light-emitting diode according to claim 1, wherein a weight ratio of the first phosphor to the second phosphor is 0.60 and to 1.5.

14. The light-emitting diode according to claim 1, comprising two light-emitting diode chips, wherein a maximum of the emission intensity of electromagnetic radiation generated by the light-emitting diode chips during operation differs by at least 5 nm.

15. A conversion element for a light-emitting diode, said conversion element provided to absorb a primary radiation and emit a secondary radiation, comprising:
a first phosphor and a second phosphor, wherein
the first phosphor has, in an absorption wavelength range (Δλ_{ab}), an absorption that decreases as the wavelength increases, and the second phosphor has, in the same absorption wavelength range (Δλ_{ab}), an absorption that increases as the wavelength increases, and
wavelengths of the maximum emission intensity of the first and second phosphors differ by at most 20 nm.

16. A light-emitting diode comprising:
a light-emitting diode chip which emits primary radiation in a spectral range of blue light during operation;
a conversion element comprising a first phosphor and a second phosphor which absorbs part of the primary radiation and re-emits secondary radiation, wherein
the first phosphor has, in an absorption wavelength range (Δλ_{ab}), an absorption that decreases as the wavelength increases, and the second phosphor has, in the same absorption wavelength range (Δλ_{ab}), an absorption that increases as the wavelength increase;
the primary radiation comprises wavelengths that lie in said absorption wavelength range (Δλ_{ab});
the light-emitting diode emits white mixed light comprising primary radiation and secondary radiation and having a color temperature of at least 4000 K;
the first phosphor is based on europium as a luminous center and the second phosphor is based on cerium as a luminous center; and
the weight ratio of the first phosphor to the second phosphor is 0.60 to 1.5.
